(19) United States
(12) Patent Application Publication
(10) Pub. No.: US 2024/0047295 A1
(43) Pub. Date: Feb. 8, 2024

(54) 3D PACKAGING WITH SILICON DIE AS THERMAL SINK FOR HIGH-POWER LOW THERMAL CONDUCTIVITY DIES

(71) Applicant: Qorvo US, Inc., Greensboro, NC (US)

(72) Inventors: George Maxim, Saratoga, CA (US); Julio C. Costa, Oak Ridge, NC (US); Dirk Robert Walter Leipold, San Jose, CA (US); Baker Scott, San Jose, CA (US)

(21) Appl. No.: 18/266,237

(22) PCT Filed: Dec. 13, 2021
(86) PCT No.: PCT/US2021/063095

§ 371 Date: Jun. 8, 2023

Related U.S. Application Data
(60) Provisional application No. 63/124,450, filed on Dec. 11, 2020.

(51) Int. Cl. H01L 23/367; H01L 23/66; H01L 25/065; H01L 23/00; H01L 23/498

(52) U.S. Cl. CPC H01L 23/3675; H01L 23/66; H01L 25/0655; H01L 24/16; H01L 23/3672; H01L 24/32; H01L 23/49816; H01L 23/49822; H01L 2223/6677; H01L 2223/6616; H01L 2224/16225; H01L 2224/16146; H01L 2224/32225; H01L 2224/32146; H01L 2924/15311; H01L 2924/13064; H01L 2924/13051; H01L 2924/01031

(57) ABSTRACT

The present disclosure relates to a three-dimensional (3D) package that has a die-on-die configuration, and includes a first die and at least one second die deposed underneath the first die. The first die includes a back-end-of-line (BEOL) portion, a device region over the BEOL portion, a substrate over the device region, and a substrate tie structure that extends through the device region and at least extends into the substrate. The substrate and the substrate tie structure each has a high thermal conductivity higher than 50 W/mK. The at least one second die is configured to be coupled to the BEOL portion of the first die, such that heat generated by the second die can propagate through the BEOL portion and the substrate tie structure, and radiate out of the first substrate.

### RELATED APPLICATIONS

This application claims the benefit of provisional patent application Ser. No. 63/124,450, filed Dec. 11, 2021, the disclosure of which is hereby incorporated herein by reference in its entirety.

### FIELD OF THE DISCLOSURE

The present disclosure relates to a three-dimensional (3D) package, and more particularly to a 3D package with a die-on-die configuration and utilizing a silicon die as a thermal sink for one or more high-power low thermal conductivity dies.

### BACKGROUND

Many radio frequency (RF) applications, such as base-stations or mobile-terminals with mmWave front-end, involve very large power dissipations that require special heat extraction elements. Typically, these large power dissipations are mainly generated by single-channel or multi-channel power amplifier dies realized in low thermal conductivity materials. Metal heat sinks are frequently used in cases where there is significant volume and height (e.g. several milimeters) that can be allocated to the heat extraction elements. However, a relatively large vertical distance between the metal heat sink and the power amplifier dies may still result in relatively high die temperatures.

On the other hand, with the popularity of portable electronic products, such as smart phones, tablet computers, and so forth, the height/thickness of the portable electronic products becomes critical. In many cases, the height requirements of the portable electronic products will not allow the use of the metal heat sinks.

Accordingly, to accommodate the low-profile requirements for portable products and to create an efficient (relatively short) low thermal resistance path for high-power low thermal conductivity dies, it is therefore an object of the present disclosure to provide an improved package design with enhanced thermal performance and a reduced package size/height without expensive and complicated processes.

### SUMMARY

The present disclosure describes a three-dimensional (3D) package with a silicon die as a thermal sink for one or more high-power low thermal conductivity dies. The disclosed 3D package includes a first die and at least one second die deposed underneath the first die. The first die includes a back-end-of-line (BEOL) portion, a first device region over the BEOL portion, a first substrate over the first device region, and a substrate tie structure that extends through the first device region and at least extends into the first substrate. Herein, the first substrate has a thermal conductivity higher than 100 W/mK, and the substrate tie structure has a thermal conductivity higher than 50 W/mK. The second die includes a second device region and a second substrate that has a thermal conductivity lower than the thermal conductivity of the first substrate and is underneath the second device region. The second device region is configured to be coupled to the BEOL portion of the first die, such that heat generated by the second device region can propagate through the BEOL portion and the substrate tie structure, and radiate out of the first substrate.

In one embodiment of the 3D package, the first device region includes one or more active sections, which are configured to provide one or more electrical device components. The substrate tie structure is laterally offset from the one or more active sections.

In one embodiment of the 3D package, the first die further includes a dielectric layer between the first device region and the first substrate. The substrate tie structure extends through the first device region and the dielectric layer, and at least extends into the first substrate.

In one embodiment of the 3D package, the dielectric layer of the first die is formed of silicon oxide or silicon nitride.

In one embodiment of the 3D package, the first substrate is in contact with the first device region without any dielectric layer in between.

In one embodiment of the 3D package, the substrate tie structure is located vertically aligned with the second die.

In one embodiment of the 3D package, the first substrate is formed of silicon.

In one embodiment of the 3D package, the second device region is configured to provide one or more electrical device components including one or more of gallium arsenide (GaAs), indium phosphide (InP), gallium nitride (GaN), gallium phosphide (GaP), gallium carbon (GaC), gallium, indium gallium arsenide (InGaAs), indium gallium nitride (InGaN), indium gallium phosphide (InGaP), indium gallium carbide (InGaC). The second substrate is formed of GaAs, GaN, GaP, or GaC.

In one embodiment of the 3D package, the second device region is configured to provide one or more heterojunction bipolar transistors (HBTs), one or more pseudomorphic high-electron mobility transistors (pHEMTs), and/or one or more field effect transistors (FETs).

In one embodiment of the 3D package, the substrate tie structure has one configuration of a grid array configuration, a multi-ring configuration, and a fish-bone configuration.

In one embodiment of the 3D package, the substrate tie structure includes at least one of a doped semiconductor, a metal powder, a plated metal and a metal compound.

According to one embodiment, the 3D package further includes a number of bump structures. The bump structures are formed at a bottom of the BEOL portion of the first die and surrounds the second die. Each bump structure has a same height and is taller than the second die. The BEOL portion of the first die includes a number of connecting structures, where certain ones of the bump structures are connected to the second device region of the second die through corresponding ones of the connecting structures.

In one embodiment of the 3D package, the bump structures are a number of copper pillars or a number of solder balls.

In one embodiment of the 3D package, certain ones of the connecting structures are coupled to the second device region of the second die, and extend through the BEOL portion of the first die, wherein the certain ones of the connecting structures are in contact with the substrate tie structure in the first die.

In one embodiment of the 3D package, the certain ones of the connecting structures are shaped to conform to a configuration of the substrate tie structure.

According to one embodiment, the 3D package further includes an antenna module, which is deposed underneath the second die and connected to the bump structures.

According to one embodiment, the 3D package further includes a mold compound and a heatsink. The mold compound covers sides of the first die, and extends vertically beyond a top surface of the first die. The heatsink is deposed over the top surface of the first die, and is embedded in the mold compound.

According to one embodiment, the 3D package further includes a mold compound, which fills gaps between the first die and the antenna module, such that the second die and the bump structures are encapsulated by the mold compound.

In one embodiment of the 3D package, outlines of the substrate tie structure at least substantially cover a horizontal area of the second die.

In one embodiment of the 3D package, the first substrate further includes a doped substrate region. Herein, the substrate tie structure is directly below the doped substrate region or extends into the doped substrate region. The doped substrate region has a higher thermal conductivity than other portions of the first substrate.

In one embodiment of the 3D package, the doped substrate region has a thickness between a few tens of micrometers and 500 micrometers, and is sized to substantially cover outlines of the substrate tie structure in a horizontal plane.

In one embodiment of the 3D package, the substrate tie structure in the first die extends through the first device region and through the first substrate.

In one embodiment of the 3D package, the substrate tie structure is hollow.

According to one embodiment, the 3D package further includes multiple dies deposed underneath the first die. Herein, the second die is one of the multiple dies, and the multiple dies are configured in a way that heat generated by these dies can radiate out of the first substrate.

In one embodiment of the 3D package, the first die includes a number of substrate tie structures including the substrate tie structure, wherein each substrate tie structure is vertically aligned with a corresponding one of the multiple dies.

According to one embodiment, the 3D package further includes a number of bump structures. Herein, the bump structures are formed at a bottom of the BEOL portion of the first die and surrounds the multiple dies. Each bump structure has a same height and is taller than each of the multiple dies. Certain ones of the bump structures are connected to certain ones of the multiple dies.

According to one embodiment, the 3D package further includes an antenna module, which is deposed underneath the multiple dies and connected to the bump structures.

According to one embodiment, the 3D package further includes a mold compound, which fills gaps between the first die and the antenna module, such that the multiple dies and the bump structures are encapsulated by the mold compound.

According to one embodiment, the 3D package further includes a printed circuit board (PCB) module deposed over the first die. Herein, the first die further includes a number of device via structures, which is configured to connect the PCB module to certain ones of the multiple dies through connecting structures in the BEOL portion of the first die, and configured to connect the PCB module to the antenna module through certain ones of the bump structures.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary 1 three-dimensional (3D) assembly including a high-power low thermal conductivity die and a thermal sink die according to one embodiment of the present disclosure.

FIGS. 2A-2C illustrate exemplary configurations of a substrate tie structure, which are configured to enhance thermal conductivity of a heat dissipation path from the high-power low thermal conductivity die to the thermal sink die.

FIGS. 3-5 illustrate an alternative die-on-die 3D assembly according to one embodiment of the present disclosure.

FIGS. 6A-6B illustrate an exemplary 3D package including the die-on-die 3D assembly shown in FIG. 1.

FIG. 7 illustrates an alternative exemplary 3D package including the alternative die-on-die 3D assembly shown in FIG. 2.

FIG. 8 illustrates a top view of an alternative 3D package including multiple high-power low thermal conductivity dies and one thermal sink die according to one embodiment of the present disclosure.

FIGS. 9A-9C illustrate a cross-section view of the 3D package shown in FIG. 8.

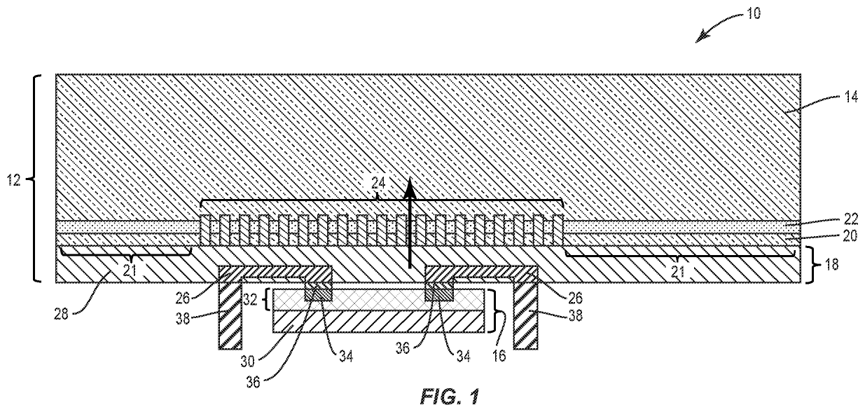

It will be understood that for clear illustrations, FIGS. 1-9C may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a three-dimensional (3D) package that has enhanced thermal dissipation performance and is compliant with the low-profile requirements. FIG. 1 illustrates an exemplary 3D die-on-die assembly 10, which may be stacked in a 3D package (more details of the 3D package described below), according to one embodiment of the present disclosure. For the purpose of this illustration, the 3D die-on-die assembly 10 includes a first die 12 having a first substrate 14 with a relatively high thermal conductivity, and a second die 16 deposed underneath the first die 12, where the first die 12 is configured to provide electrical functions and also configured as a thermal sink for the second die 16. In different applications, the 3D die-on-die assembly 10 may include multiple second dies 16, which are deposed underneath the first die 12 and utilize the first die 12 as a thermal sink.

In detail, the first die 12 includes a back-end-of-line (BEOL) portion 18, underneath which the second die 16 is formed, a first device region 20 over the BEOL portion 18, a dielectric layer 22 over the first device region 20, the first substrate 14 over the dielectric layer 22, and a substrate tie structure 24 that extends through the first device region 20 and the dielectric layer 22 and extends into the first substrate 14. The BEOL portion 18, which is configured to connect the first device region 20 to external components (e.g., configured to accommodate the second die 16), includes multiple connecting structures 26 (only two connecting structures 26 are illustrated herein for simplicity) and inter-layer dielectrics 28. The connecting structures 26 may be formed of a metal/alloy material, such as copper. Some of the connecting structures 26 (for internal connection) are fully encapsulated by the inter-layer dielectrics 28 (not shown), while some of the connecting structures 26 have bottom portions not covered by the inter-layer dielectrics 28 for external connections.

The first device region 20 may be a front-end-of-line (FEOL) portion and includes one or more active sections 21 that are configured to provide one or more electrical device components, such as switch field-effect transistors (FETs), diodes, capacitors, resistors, and/or inductors (not shown). The dielectric layer 22 over the first device region 20 may be formed of silicon oxide, silicon nitride, or other compounds, which may have a relatively low thermal conductivity no higher than 10 W/mK (typical silicon-dioxide has a thermal conductivity around 0.03 W/mK). The first substrate 14 over the dielectric layer 22 may be formed of silicon or other semiconductor materials with a good thermal conductivity higher than 100 W/mK, which is close to thermal conductivities of many metals (e.g., Zinc=123 W/mK). Metals with best thermal conductivity are Copper (around 400 W/mK) and Gold (around 300 W/mK) For instance, the first die 12 may be formed from a silicon on insulator (SOI) wafer or a silicon on sapphire (SOS) wafer.

Although the first substrate 14 (e.g., silicon substrate) provides decent heat dissipation capabilities, the first substrate 14 is isolated from the device region 20 (which generates heat) and the BEOL portion 18 (which propagates heat from the second die 16, details described below) by the dielectric layer 22, which may have a low thermal conductivity (below 10 W/mK and in most case below few W/mK). As such, the dielectric layer 22 may limit heat dissipation through the first substrate 14. The substrate tie structure 24, which extends from a top surface of the BEOL portion 18, through the first device region 20 and the dielectric layer 22, and into the first substrate 14, is introduced to enhance heat dissipation efficiency of a thermal path from the BEOL portion 18 to the first substrate 14. In one embodiment, if the dielectric layer 22 is a very thin layer, it can provide a good electrical isolation, but may not be that bad in terms of equivalent thermal resistance.

In some applications, the dielectric layer 22 may not be present in the first die 12, such that the first substrate 14 is directly over the first device region 20 (not shown). For instance, the first die 12 may be formed by bulk-semiconductor processes. Herein, the substrate tie structure 24 may still exist, and extends from the top surface of the BEOL portion 18, through the first device region 20, and into the first substrate 14 (not shown).

The BEOL portion 18 has a thickness between a few micrometers for the cases where the connecting structures 26 distributed in few metal layers (e.g., 2, 3, 4 metal layers) and a few tens of micrometers for the cases where the connecting structures 26 distributed in a large number of metal layers (e.g., 8,10,13,16, etc. metal layers). The first device region 20 has a thickness between tens or hundreds of nano-meters and a few micrometers depending on fabricating processes. The dielectric layer 22, if exists, has a thickness between 100 nanometer (or even lower) and one or several micrometers. The first substrate has a thickness between 20 micrometers and 450 micrometers. In order to penetrate through the first device region 20 and the dielectric layer 22, the substrate tie structure 24 need to have a height larger than a thickness combination of the first device region 20 and the dielectric layer 22, between hundreds of micrometers and several micrometers or tens of micrometers, for instance. In the cases where the dielectric layer 22 is omitted, the substrate tie structure 24 need to have a height larger than the thickness of the first device region 20.

The substrate tie structure 24 may include a high thermal conductivity material, such as doped silicon or metal powders or compounds, with a thermal conductivity higher than 50 W/mK (e.g., a typical value is around 100 W/mK). Notice that since the first device region 20 includes one or more active sections 21 configured to provide electrical device components and the substrate tie structure 24 penetrates through the first device region 20, it is desirable that the substrate tie structure 24 is laterally offset from the active sections 21.

The second die 16 includes a second substrate 30, a second device region 32 over the second substrate 30, and multiple die contacts 34 (only two die contacts 34 are illustrated herein for simplicity) at a top of the second device region 32. Typically, the second die 16 has a much smaller size (at least in a horizontal plane) compared to the first die 12. However, the second die 16, in particular the second device region 32, will generate a much higher volume of heat than the first die 12.

The second device region 32 may be configured to provide one or more high power device components, such as heterojunction bipolar transistors (HBTs), pseudomorphic high-electron mobility transistors (pHEMTs), and/or one or more field effect transistors (FETs). These high power device components may be realized in Ill-V processes utilizing Ill-V materials, such as gallium arsenide (GaAs), indium phosphide (InP), gallium nitride (GaN), gallium phosphide (GaP), gallium carbon (GaC), gallium, indium gallium arsenide (InGaAs), indium gallium nitride (InGaN), indium gallium phosphide (InGaP), indium gallium carbide (InGaC), and the like. On the other hand, the second substrate 30 for the high power second device region 32 is typically formed of a low thermal conductivity material (such as GaAs, GaN, InN, or GaC), which has a thermal conductivity no higher than 70 W/mK (e.g., GaAs 32 W/mK, InN 45 W/mK, InP 68 W/mK at 300K, the thermal conductivities varying with temperature). Typically, the thermal conductivity of the second substrate 30 is several times smaller than the first substrate 14 in the first die 12 (e.g., silicon, or doped silicon that has an even higher thermal conductivity, closer to metals). Therefore, the heat generated by the second device region 32 may not effectively dissipate through the second substrate 30.

Herein, the second die 16 is deposed underneath the first die 12 via an attaching material 36 (e.g., solder or other compounds, or alternatively any metal bonding technique), where the die contacts 34 at the top of the second device region 32 are thermally and electrically connected to the exposed bottom portions of the connecting structures 26 in the BEOL portion 18 of the first die 12 via the attaching material 36. In consequence, the heat generated by the second device region 32 can propagate through the BEOL portion 18 (e.g., mainly through the connecting structures 26) and the substrate tie structure 24, and finally radiate out of the first substrate 14. For a superior thermal performance, it is desirable that the substrate tie structure 24 is located vertically aligned with the second die 16, so as to provide a shortest thermal path from the second device region 32 to the first substrate 14 (via the BEOL portion 18 and the substrate tie structure 24). Typically, outlines of the substrate tie structure 24 at least substantially covers a horizontal area of the second die 16.

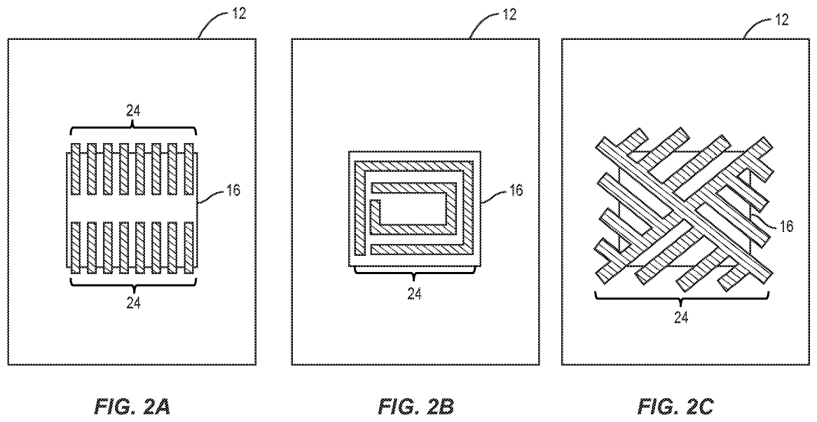

Furthermore, the 3D die-on-die assembly 10 may further include multiple bump structures 38 formed at a bottom of the first die 12 (i.e., at a bottom of the BEOL portion 18) and surrounding the second die 16. The bump structures 38 may be electrically connected to the second device region 32 of the second die 16 through the connecting structures 26 in the BEOL portion 18 of the first die 12, and may be electrically connected to the first device region 20 of the first die 12 through some other connecting structures (not shown). The bump structures 38 may be copper pillars or solder balls (see FIG. 2).

In the second die 16, the second substrate 30 has a thickness from few/few tens of micrometers (in extreme cases), to 150˜200 micrometers, or even to a native thickness of a wafer (several hundreds of micrometers). The second device region 32 has a thickness between tens or hundreds of nanometers and few micrometers, depending on the fabricating processes. The second die may have a poor thermal conductance, so its thickness is only set by the mechanical strength for assembly. In many cases, the second die 16 (i.e., the second substrate 30) is thinned to fit together with the bump structure 38 of the 3D die-on-die assembly 10. Herein, each bump structure 38 has a same height and is taller than the second die 16 to meet further packaging requirements (more details are described below).

FIGS. 2A-2C illustrate a top view of an exemplary configuration of the substrate tie structure 24. The substrate tie structure 24 may have a grid array configuration (shown in FIG. 2A), a multi-ring configuration (shown in FIG. 2B), and a fish-bone configuration (shown in FIG. 2C). However, the configuration of the substrate tie structure 24 is not limited to these exemplary configurations.

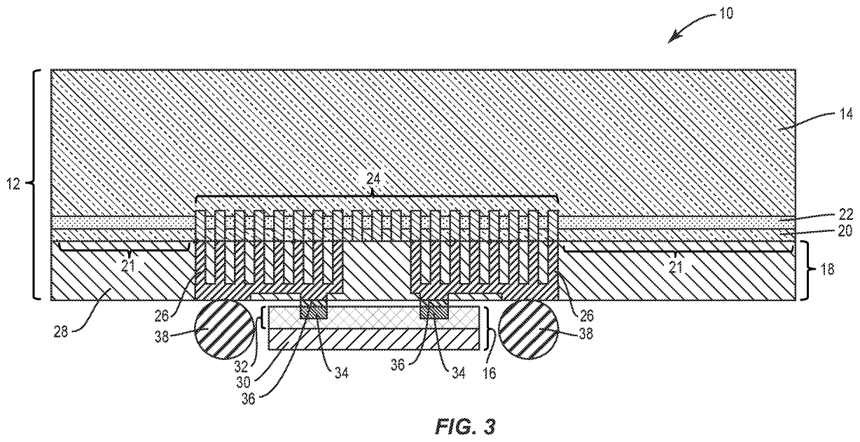

In some applications, to further boost the thermal conductance of the thermal path between the high power second die 16 and the first substrate 14 of the first die 12, certain ones of the connecting structures 26, which are coupled to the second die 16 (i.e., the second device region 32), may extend through the BEOL portion 18 of the first die 12 (i.e., through the inter-layer dielectrics 28 of the BEOL portion 18), as illustrated in FIG. 3. Herein, the connecting structures 26 are connected to the die contacts 34 of the second die 16 via the attaching material 36 and are directly connected to the substrate tie structure 24 in the first die 12. The connecting structures 26 may be shaped to conform to the configuration of the substrate tie structure 24. Since the connecting structures 26 are formed of a metal/alloy material and directly connect the substrate tie structure 24 to the second die 16, the thermal conductance of the thermal path between the second die 16 and the first substrate 14 is further enhanced. In FIG. 3, the bump structures 38 are shown as BGA, which is still taller than the second die 16.

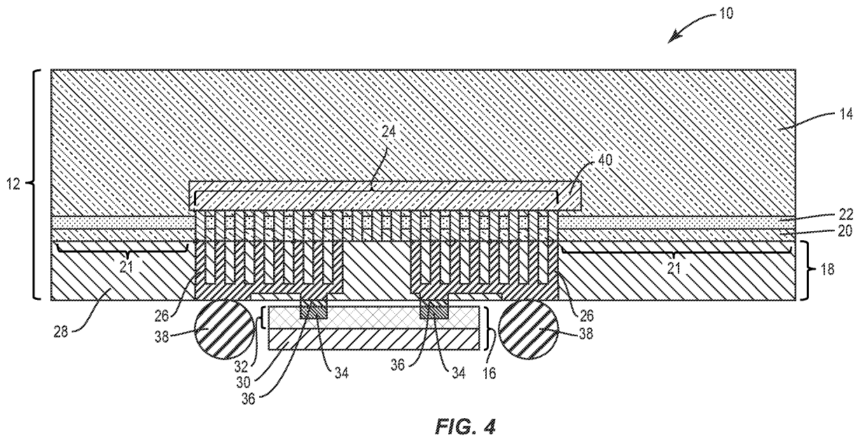

In some applications, the first substrate 14 of the first die 12 may include a doped substrate region 40 above the substrate tie structure 24, as illustrated in FIG. 4. The doped substrate region 40 may include one or more doper materials, such as Borum, Indium, Gallium, Aluminum for P-type, and Phosphorus, Arsenic, Antimony, Bismuth or Lithium for N-type. The doping concentrations can be between 1e+13 cm−3 for low doping and 1e+18 cm−3 for high doping. The doping concentration above 1e+18 cm−3 may result in degenerate silicon with metal like proprieties. The doped substrate region 40 may have a thermal conductivity higher than the rest of the portions of the first substrate 14 (e.g., higher than 100 W/mK) and a thickness up to several hundreds of micrometers as needed (e.g., between several tens of micrometers and 500 micrometers). The thicker the silicon substrate is the better it will act as a heat sink for the second die with high power dissipation. The doped substrate region 40 may be sized to substantially cover the outlines of the substrate tie structure 24 in a horizontal plane (e.g., about the same as or larger than the outlines of the substrate tie structure 24). In one embodiment, the substrate tie structure 24 is directly below the doped substrate region 40 or extends into the doped substrate region 40 (not shown). Since the doped substrate region 40 has a lower thermal resistance than remaining regions of the first substrate, the doped substrate region 40 further improves the dissipation of heat propagated from the substrate tie structure 24.

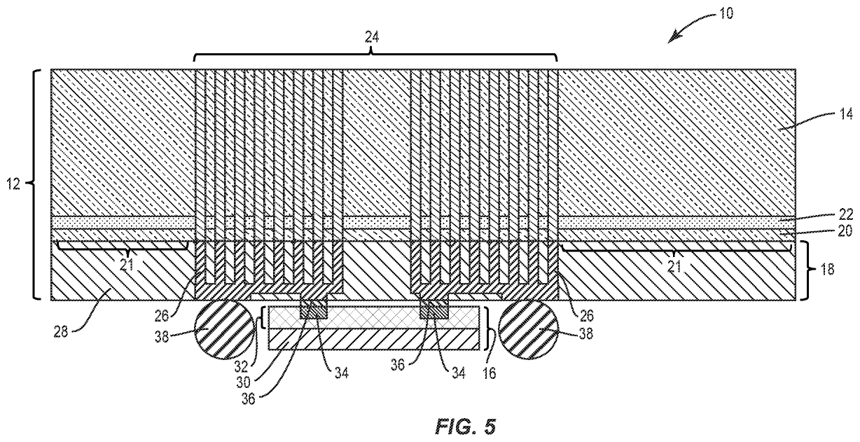

As described above, the first die 12 includes the substrate tie structure 24, which extends through the first device region 20 and the dielectric layer 22, and extends into the first substrate 14, to enhance heat dissipation efficiency of the thermal path from the BEOL portion 18 to the first substrate 14. In some applications, the substrate tie structure 24 may extend through the first device region 20, through the dielectric layer 22, and further through the first substrate 14, and may be in contact with the connecting structures 26, as illustrated in FIG. 5. In this case, the substrate tie structure 24 may have a height of hundreds of micrometers. The substrate tie structure 24 may be hollow or filled with high thermal materials, such as silver and/or metal compounds, with a thermal conductivity higher than 100 W/mK, and in many cases in several hundreds of W/mK. The substrate tie structure 24 may include through-silicon vias (TSVs).

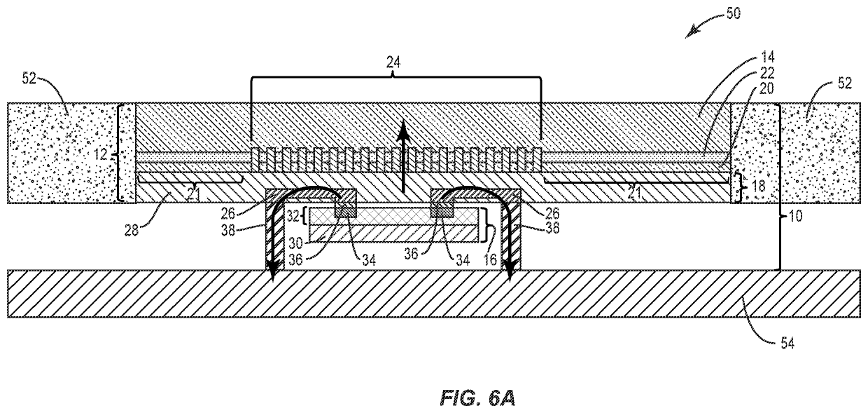

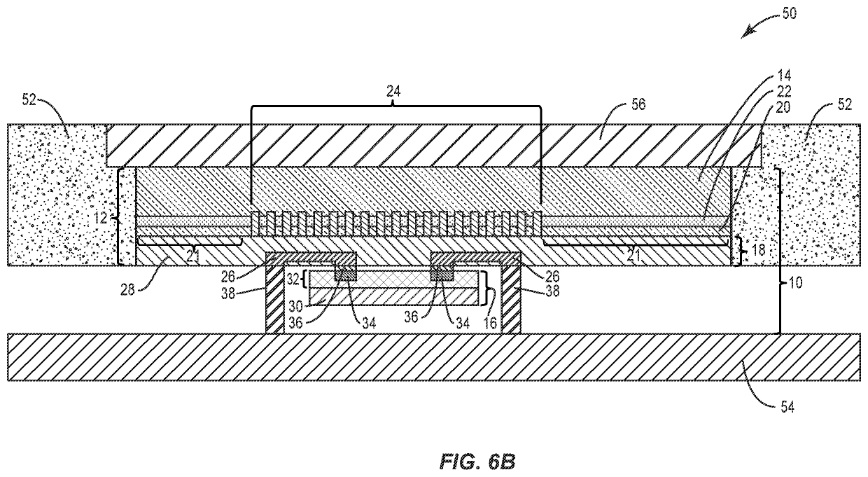

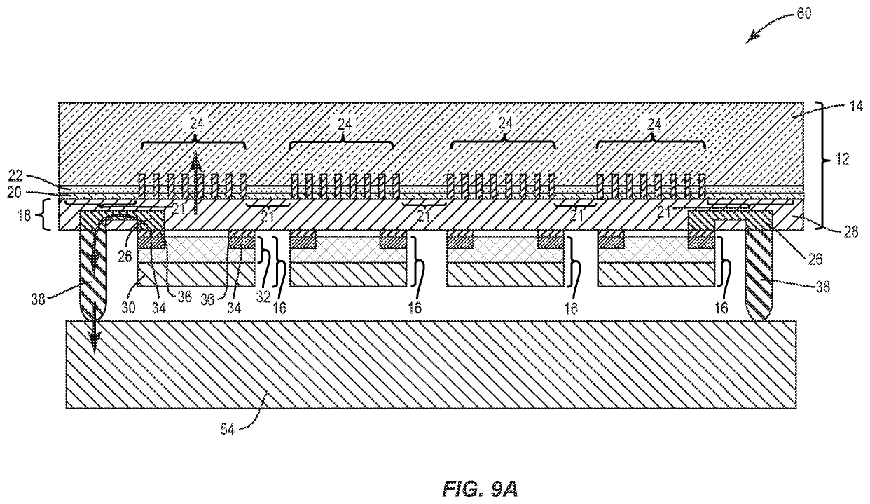

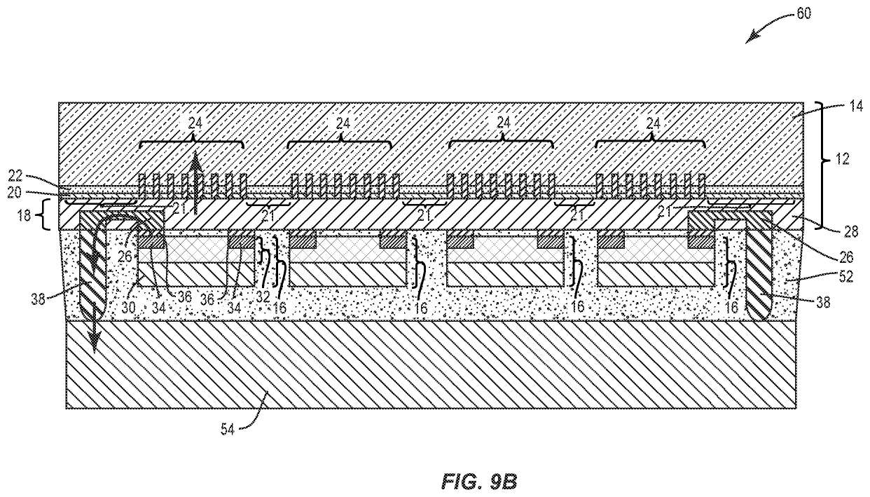

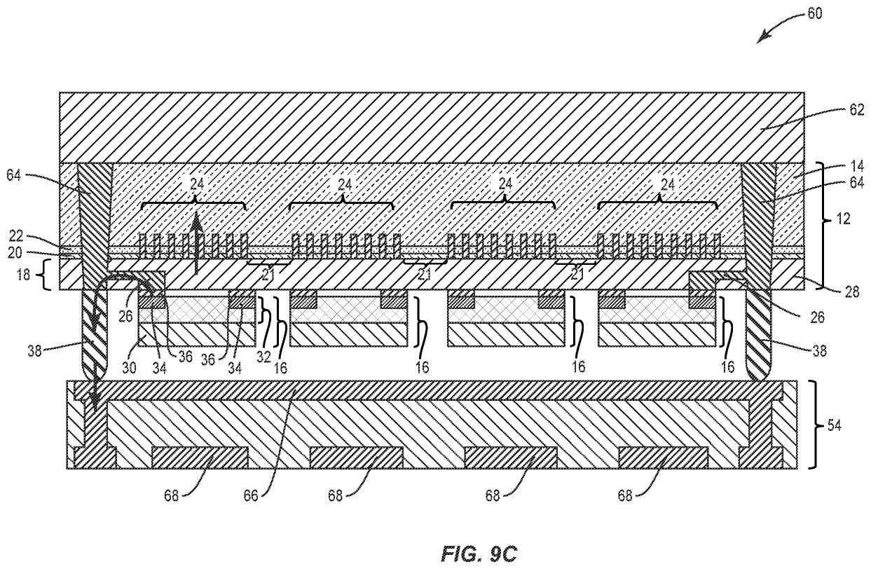

FIGS. 6A-6B illustrate an exemplary 3D package 50 including the die-on-die 3D assembly 10 shown in FIG. 1. Besides the die-on-die 3D assembly 10, the 3D package 50 may further include a mold compound 52 and an antenna module 54, as illustrated in FIG. 6A. For the purpose of this illustration, the mold compound 52 covers sides of the first die 12, and has top and bottom surfaces that are coplanar with top and bottom surfaces of the first die 12, respectively. In some applications, portions of the mold compound 52 may reside over the first die 12, and/or underfill the first die 12 to encapsulate the second die 16 and the bump structures 38 (not shown). In some applications, the mold compound 52 may be omitted (see FIG. 9A shown below). In some applications, the mold compound 52 may only underfill the first die 12 to encapsulate the second die 16 and the bump structures 38, but does not cover the sides and the top surface of the first die 12 (see FIG. 9B shown below).

The antenna module 54 is deposed underneath the second die 16 and is connected to the bump structures 38. Since the bump structures 38 may be electrically connected to the first die 12 and the second die 16 (as described above), signals received from the antenna module 54 can be transmitted to the first die 12 and/or the second die 16. In this embodiment, the heat generated by the second die 16 (i.e., the second device region 32) can still propagate through the BEOL portion 18 and the substrate tie structure 24, and radiate out of the first substrate 14. In addition, the heat generated by the second die 16 may also propagate towards the antenna module 54 through the connecting structures 26 in the BEOL portion 18 and the bump structures 38. Herein, since the bump structures 38 are taller than the second die 16, the second die 16 will not be in contact with the antenna module 54.

The mold compound 52 may be formed of thermoplastics or thermoset polymer materials, such as polyphenylene sulfide (PPS), overmold epoxies doped with boron nitride, alumina, carbon nanotubes, or diamond-like thermal additives, or the like. The antenna module 54 may provide a patch antenna (see FIG. 9C) and may comprises ceramic, FR4, or etc . . . .

In some applications, the 3D package 50 may further include a heatsink 56 above the first die 12, as illustrated in FIG. 6B. For the purpose of this illustration, the mold compound 52 covers the sides of the first die 12 and extends vertically beyond the top surface of the first die 12. The heatsink 56 is in contact with a top surface of the first substrate 14 (i.e., the top surface of the first die 12) and embedded in the mold compound 52. A top surface of the heatsink 56 and the top surface of the mold compound 52 may be coplanar. The heatsink 56 may be formed of a metal/alloy material, such as Copper or Nickel in the case of plated metal shields. The metal shield can also be sprayed.

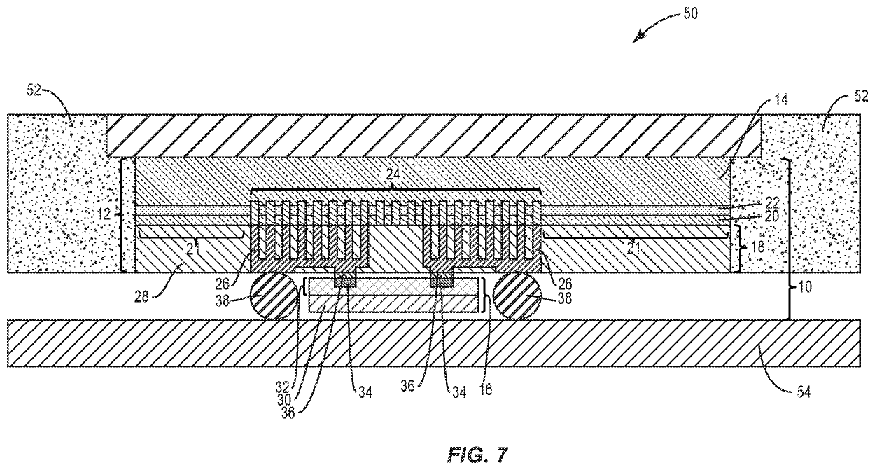

Notice that, in FIGS. 6A-6B, the 3D package 50 includes the 3D die-on-die assembly 10 illustrated in FIG. 1. In different applications, the 3D package 50 may include the 3D die-on-die assembly 10 illustrated in any of FIGS. 3-5, or any other proper 3D die-on-die assemblies. For instance, FIG. 7 shows that the 3D package 50 includes the 3D die-on-die assembly 10 illustrated in FIG. 2. Herein, the antenna module 54 is still deposed underneath the second die 16 and is connected to the bump structures 38 (i.e., BGA). The signals received from the antenna module 54 can be transmitted to the first die 12 and/or the second die 16 through the bump structures 38 and the connecting structures 26. A majority of the heat generated by the second die 16 will still dissipate through the first substrate 14, because of the through-BEOL connecting structures 26. There is a portion of the heat generated by the second die 16 that may also propagate towards the antenna module 54 through the bump structures 38.

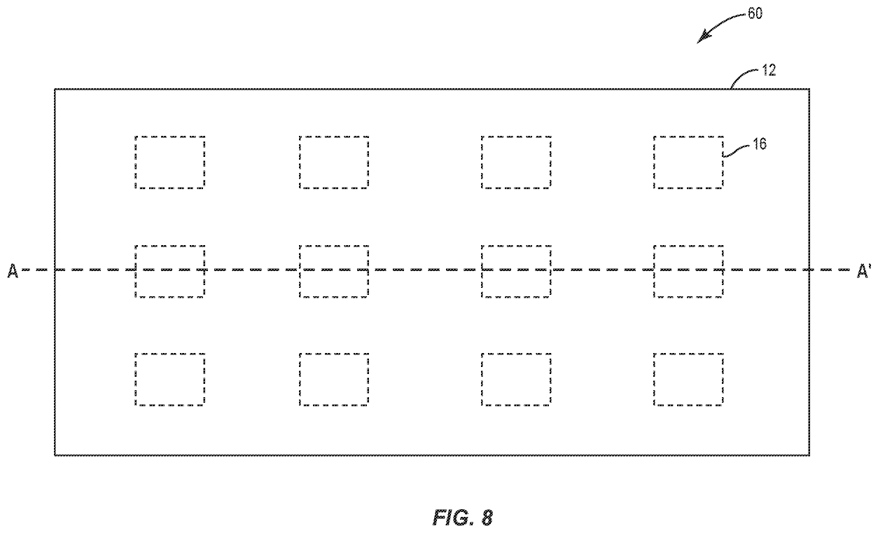

FIG. 8 illustrates a top view of a 3D package including multiple high-power low thermal conductivity dies and a silicon die as a thermal sink for the multiple high-power low thermal conductivity dies according to one embodiment of the present disclosure.

In some applications, there might be multiple high-power low thermal conductivity dies deposed underneath one thermal sink die. FIG. 8 illustrates a top view of an alternative 3D package 60 including multiple high power second dies 16 underneath one first die 12 (only one second die is labeled with a reference number for clarity). For the purpose of this illustration, the alternative 3D package 60 includes twelve second dies 16 underneath the first die 12 which are configured in a 3×4 array. For different applications, the alternative 3D package 60 may include fewer or more second dies 16 with a different array configuration.

FIGS. 9A-9C illustrate a cross-section view (along dashed line A-A′) of the alternative 3D package 60 shown in FIG. 8. Compared to the 3D package 50 shown in FIGS. 6A-6B, the alternative 3D package 60 includes multiple second dies 16 (elements in only one second die 16 are labeled with reference numbers for clarity) that are deposed underneath the first die 12 and surrounded by the bump structures 38, and multiple substrate tie structures 24 that extend through the first device region 20 and the dielectric layer 22 of the first die 12 and extend into the first substrate 14 of the first die 12, as illustrated in FIG. 9A. For the purpose of this illustration, each second die 16 has a same size and a same height, each substrate tie structure 24 corresponds to one second die 16, and each substrate tie structure 24 has a same shape with same outlines. For different applications, these multiple second dies 16 may provide different high-power device components and may have different sizes and/or different heights. One large substrate tie structure 24 may serve more than one second die 16. Also, the multiple substrate tie structures 24 may have different shapes and/or different outlines. Notice that since the first device region 20 includes one or more active sections 21 configured to provide electrical device components and each substrate tie structure 24 penetrates through the first device region 20, it is desirable that each substrate tie structure 24 is laterally offset from the active sections 21.

Herein, at least some of the second dies 16 are electrically connected to certain bump structures 38 by corresponding connecting structures 26 in the BEOL portion 18 of the first die 12 (only two connecting structures 26 are illustrated herein for simplicity). These multiple second dies 16 may be electrically connected to each other and/or electrically connected to the first die 12 by other connecting structures 26 in the BEOL portion 18 (not shown). Each bump structure 38 still extends from the bottom surface of the first die 12 to the top surface of the antenna module 54, and electrically connects the first die 12/the second die(s) 16 (i.e., the first device region 22/the second device region 32) to the antenna module 54. The bump structures 38 may have a same height and are taller than each of the second dies 16.

In this embodiment, the heat generated by each second die 16 can propagate through the BEOL portion 18 and the substrate tie structure 24, and radiate out of the first substrate 14 of the first die 12. If a certain second die 16 is connected to the bump structure 38, the heat generated by such second die 16 may also propagate towards the antenna module 54 through the connecting structures 26 in the BEOL portion 18 and the bump structures 38.

In one embodiment, the alternative 3D package 60 may further include the mold compound 52, as illustrated in FIG. 9B. For the purpose of this illustration, the mold compound 52 underfills the first die 12 to encapsulate each second die 16 and each bump structure 38, but does not cover the sides and the top surface of the first die 12. In some applications, the mold compound 52 may further cover the sides of the first die 12, or fully encapsulate the first die 12 (not shown). If the mold compound 52 has a high thermal conductivity (e.g., >30 W/m·K), the heat generated by the second die 16 may also dissipate through the mold compound 52.

In one embodiment, the alternative 3D package 60 may further include a printed circuit board (PCB) module 62 over the first die 12, as illustrated in FIG. 9C. Herein, the first die 12 further includes device via structures 64, which are configured to connect the PCB module 62 to corresponding bump structures 38. The device via structures 64 may penetrate vertically through the first die 12 and may comprise a conductive material, such as copper. The device via structures 64 may be TSVs. The antenna module 54, the PCB module 62, and certain second dies 16 may be electrically and/or thermally connected through the corresponding bump structures 38, corresponding device via structures 64, and corresponding connecting structures 26 in the BEOL portion 18. In consequence, the heat generated by the second dies 16 may dissipate through the die structure 24 and the first substrate 14, through the bump structure 38 and the antenna module 54, and/or through the device via structures 64 and the PCB module 62.

The antenna module 54 in this embodiment provides a patch antenna, which includes multiple metal patches 66 at a bottom of the antenna module 54. In addition, the antenna module 54 may also include a ground plane structure 68, which may provide electrical ground level to some second dies 16 through the bump structure 38.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A three-dimensional (3D) package comprising:
a first die including a back-end-of-line (BEOL) portion, a first device region over the BEOL portion, a first substrate over the first device region, and a substrate tie structure that extends through the first device region and extends into the first substrate, but does not extend through the first substrate, wherein:
the first substrate has a thermal conductivity higher than 100 W/mK, and the substrate tie structure has a thermal conductivity higher than 50 W/mK; and
a second die deposed underneath the first die, wherein:
the second die includes a second device region and a second substrate underneath the second device region;
the second substrate has a thermal conductivity lower than the thermal conductivity of the first substrate; and
the second device region is configured to be coupled to the BEOL portion of the first die, such that heat generated by the second device region can propagate through the BEOL portion and the substrate tie structure, and radiate out of the first substrate.

2. The 3D package of claim 1 wherein:
the first device region includes one or more active sections, which are configured to provide one or more electrical device components; and
the substrate tie structure is laterally offset from the one or more active sections.

3. The 3D package of claim 1 wherein:
the first die further includes a dielectric layer between the first device region and the first substrate; and
the substrate tie structure extends through the first device region and the dielectric layer, and extends into the first substrate but does not extend through the first substrate.

4. The 3D package of claim 3 wherein the dielectric layer of the first die is formed of silicon oxide or silicon nitride.

5. The 3D package of claim 1 wherein the first substrate is in contact with the first device region without any dielectric layer in between.

6. The 3D package of claim 1 wherein the substrate tie structure is located vertically aligned with the second die.

7. The 3D package of claim 1 wherein the first substrate is formed of silicon.

8. The 3D package of claim 1 wherein:
the second device region is configured to provide one or more electrical device components comprising one or more of gallium arsenide (GaAs), indium phosphide (InP), gallium nitride (GaN), gallium phosphide (GaP), gallium carbon (GaC), gallium, indium gallium arsenide (InGaAs), indium gallium nitride (InGaN), indium gallium phosphide (InGaP), indium gallium carbide (InGaC); and
the second substrate is formed of GaAs, GaN, GaP, or GaC.

9. The 3D package of claim 8 wherein the second device region is configured to provide one or more heterojunction bipolar transistors (HBTs), one or more pseudomorphic high-electron mobility transistors (pHEMTs), and/or one or more field effect transistors (FETs).

10. The 3D package of claim 1 wherein the substrate tie structure has one configuration of a grid array configuration, a multi-ring configuration, and a fish-bone configuration.

11. The 3D package of claim 1 wherein the substrate tie structure comprises at least one of a doped semiconductor, a metal powder, a plated metal and a metal compound.

12. The 3D package of claim 1 further comprising a plurality of bump structures, wherein:
the plurality of bump structures is formed at a bottom of the BEOL portion of the first die and surrounds the second die;
each of the plurality of bump structures has a same height and is taller than the second die; and
the BEOL portion of the first die includes a plurality of connecting structures, wherein certain ones of the plurality of bump structures are connected to the second device region of the second die through corresponding ones of the plurality of connecting structures.

13. The 3D package of claim 12 wherein the plurality of bump structures is a plurality of copper pillars or a plurality of solder balls.

14. The 3D package of claim 12 wherein certain ones of the plurality of connecting structures are coupled to the second device region of the second die, and extend through the BEOL portion of the first die, wherein the certain ones of the plurality of connecting structures are in contact with the substrate tie structure in the first die.

15. The 3D package of claim 14 wherein the certain ones of the plurality of connecting structures are shaped to conform to a configuration of the substrate tie structure.

16. The 3D package of claim 12 further comprising an antenna module, which is deposed underneath the second die and connected to the plurality of bump structures.

17. The 3D package of claim 16 further comprising a mold compound and a heatsink, wherein:
the mold compound covers sides of the first die, and extends vertically beyond a top surface of the first die; and
the heatsink is deposed over the top surface of the first die, and is embedded in the mold compound.

18. The 3D package of claim 16 further comprising a mold compound, which fills gaps between the first die and the antenna module, such that the second die and the plurality of bump structures are encapsulated by the mold compound.

19. The 3D package of claim 1 wherein outlines of the substrate tie structure at least substantially cover a horizontal area of the second die.

20. The 3D package of claim 1 wherein the first substrate further includes a doped substrate region, wherein:
the substrate tie structure is directly below the doped substrate region or extends into the doped substrate region; and
the doped substrate region has a higher thermal conductivity than other portions of the first substrate.

21. The 3D package of claim 20 wherein the doped substrate region has a thickness between several tens of micrometers and 500 micrometers, and is sized to substantially cover outlines of the substrate tie structure in a horizontal plane.

22. (canceled)

23. The 3D package of claim 22 wherein the substrate tie structure is hollow.

24. The 3D package of claim 1 further comprising a plurality of dies deposed underneath the first die, wherein:
the second die is one of the plurality of dies; and
the plurality of dies is configured in a way that heat generated by the plurality of dies can radiate out of the first substrate.

25. The 3D package of claim 24 wherein the first die comprises a plurality of substrate tie structures including the substrate tie structure, wherein each of the plurality of substrate tie structures is vertically aligned with a corresponding one of the plurality of dies.

26. The 3D package of claim 24 further comprising a plurality of bump structures, wherein:
the plurality of bump structures is formed at a bottom of the BEOL portion of the first die and surrounds the plurality of dies;
each of the plurality of bump structures has a same height and is taller than each of the plurality of dies; and
certain ones of the plurality of bump structures are connected to certain ones of the plurality of dies.

27. The 3D package of claim 26 further comprising an antenna module, which is deposed underneath the plurality of dies and connected to the plurality of bump structures.

28. The 3D package of claim 27 further comprising a mold compound, which fills gaps between the first die and the antenna module, such that the plurality of dies and the plurality of bump structures are encapsulated by the mold compound.

29. The 3D package of claim 27 further comprising a printed circuit board (PCB) module deposed over the first die, wherein the first die further includes a plurality of device via structures, which is configured to connect the PCB module to certain ones of the plurality dies through connecting structures in the BEOL portion of the first die, and configured to connect the PCB module to the antenna module through certain ones of the plurality of bump structures.
